(19) United States
(12) Patent Application Publication
(10) Pub. No.: US 2025/0202378 A1
(43) Pub. Date: Jun. 19, 2025

(54) Configurable Drive System

(71) Applicant: Eaton Intelligent Power Limited, Dublin (IE)

(72) Inventors: Hua Qiang Li, Menomonee Falls, WI (US); Geraldo Nojima, Fort Mill, SC (US); Adam Krug, Menomonee Falls, WI (US); Henrique Teixeira Braga, Belo Horizonte (BR)

(21) Appl. No.: 18/540,073

(22) Filed: Dec. 14, 2023

(51) Int. Cl. H02M 5/458; H02M 1/44

(52) U.S. Cl. CPC H02M 5/458; H02M 1/44

(57) ABSTRACT

A drive system includes: a structure; an input including: a first input section on a first side of the structure; and a second input section on a second side of the structure; an output including: a first output section on the first side of the structure; and a second output section on the second side of the structure; and a power converter electrically connected to the output and the input.

### TECHNICAL FIELD

This disclosure relates to a configurable drive system.

### BACKGROUND

A power converter, such as a variable speed drive, an adjustable speed drive, or an uninterruptable power supply, may be connected to an alternating current (AC) high-power electrical distribution system, such as a power grid. The power converter drives, powers, and/or controls a machine, or a non-machine type of load.

### SUMMARY

In one aspect, a drive system includes: a structure; an input including: a first input section on a first side of the structure; and a second input section on a second side of the structure; an output including: a first output section on the first side of the structure; and a second output section on the second side of the structure; and a power converter electrically connected to the output and the input.

Implementations may include one or more of the following features.

The structure may be configured for rotation between a first position and a second position, and, in the first position, the first side faces a first direction, and in the second position, the second side faces the first direction. The structure may be configured for placement in a first type of mounting arrangement in the first position, and the structure may be configured for placement in a second type of mounting arrangement in the second position. The first type of mounting arrangement may include a wall mount arrangement, and the second type of mounting arrangement includes a floor mount arrangement.

The first side of the mounting structure may be in a first plane and the second side of the mounting structure may be in a second plane that is perpendicular to the first plane.

The first side of the mounting structure and the second side of the mounting structure may be in different planes.

The first input section may be electrically connected to the second input section; and the first output section may be electrically connected to the second output section.

The power converter includes: a rectifier electrically connected to the input; an energy storage apparatus electrically connected to the rectifier; and an inverter electrically connected to the energy storage apparatus and to the output. The drive system also may include a filter module. The filter module may be between the input and the rectifier. The filter module may include a plurality of inductors. The filter module may be between the rectifier and the energy storage apparatus. The filter module may include at least one inductor. The filter module may include a first inductor in a positive DC bus and a second inductor in a negative DC bus.

The drive system also may include a busbar subassembly. The busbar assembly may electrically connect the input and the power converter, and the busbar assembly may electrically connects the power converter and the output.

In another aspect, a busbar subassembly for connecting a first drive system and a second drive system in parallel includes: a first electrically conductive busbar configured to electrically connect to a first drive system, the first electrically conductive busbar including: a first mounting portion that extends along a first direction, and a first connection portion that extends from the first mounting portion in a second direction; and a second electrically conductive busbar configured to electrically connect to a second drive system, the second electrically conductive busbar including: a second mounting portion that extends along the first direction, and a second connection portion that extends from the second mounting portion in the second direction. The first connecting portion is configured for electrical connection to the second connection portion to thereby electrically connect the first drive system and the second drive system in parallel.

Implementations may include one or more of the following features.

The first direction and the second direction may be perpendicular.

The first electrically conductive busbar and the second electrically conductive busbar may be L-shaped.

The first mounting portion may include at least one opening configured to receive a connector that protrudes from a busbar on the first drive system, and the second mounting portion may include at least one opening configured to receive a connector that protrudes from a busbar on the second drive system.

Each of the first connection portion and the second connection portion may include a planar surface, and the planar surfaces may be placed in physical contact to electrically connect the first connection portion and the second connection portion.

In another aspect, a drive system includes: a support; an input section configured to electrically connect to an external alternating current (AC) source; a rectifier electrically connected to the input section; an inverter; a DC link electrically connected to the rectifier and the inverter; and a filter system electrically connected to the input section and the rectifier, the filter system being internal to the support.

The support may be configured for rotation between a first position and a second position.

Implementations of any of the techniques described herein may include an apparatus, a device, a drive system, a busbar assembly, and/or a method. The details of one or more implementations are set forth in the accompanying drawings and the description below. Other features will be apparent from the description and drawings, and from the claims.

### DRAWING DESCRIPTION

FIG. 1A is a perspective block diagram of a drive system.

FIGS. 1B and 1C show a facility in which the drive system of FIG. 1A may be installed.

FIG. 2A is a schematic of a system.

FIG. 2B is a schematic of another system.

FIG. 3 is an exploded perspective view of a three-phase drive system.

FIG. 4A is a perspective view of the three-phase drive system of FIG. 3 in an assembled state.

FIG. 4B shows the top side of the assembled drive system of FIG. 4A.

FIG. 4C is a block diagram of an input busbar.

FIG. 5A shows one side of the assembled drive system of FIG. 4A.

FIG. 5B shows another side of the assembled drive system of FIG. 4A.

FIG. 6A is a perspective view of two drive systems and two busbar assemblies.

FIG. 6B is a perspective view of two drive systems, each having an attached busbar assembly.

FIG. 6C is a perspective view of two drive systems connected in parallel.

FIG. 6D is a top cross-sectional view of input busbars.

FIG. 6E is a detailed view of the inset labeled 678 in FIG. 6C.

FIG. 6F is a side view of a parallel-connected cabinet-mounted system.

FIG. 7 is a side view of a parallel-connected wall-mounted system.

FIG. 8 is a perspective interior view of another three-phase drive system.

FIG. 9 is a perspective view of an AC inductor system.

FIGS. 10A and 10B are perspective interior views of another three-phase drive system.

FIGS. 11A and 11B are perspective views of busbars and electrical connections to a rectifier system.

### DETAILED DESCRIPTION

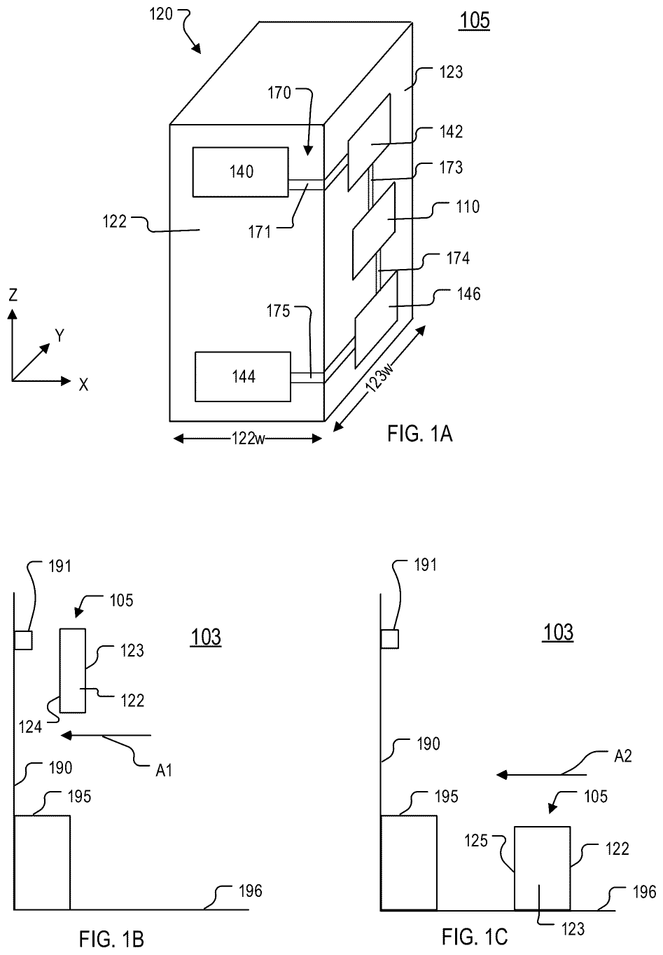

FIG. 1A is a perspective block diagram of a drive system 105. The drive system 105 is configurable and can be wall mounted or floor mounted. Furthermore, the drive system 105 includes a busbar assembly 170 that allows for design variations and makes it possible for the manufacturer to customize the drive system 105 using either internal AC (alternating current) inductors or an internal DC (direct current) choke. The busbar assembly 170 includes a plurality of busbars that connect various components of the drive system 105. The distribution of the components of the drive system 105 is such that the connections between and among the components is linear and/or direct. As a result, the busbars in the busbar assembly 170 have relatively simple shapes and are easy to manufacture. Furthermore, the busbar assembly 170 includes fasteners that are in locations that are easily accessible, thereby facilitating assembly, disassembly, and/or connection of the various components (for example, an inverter) of the drive system 105. The busbar assembly 170 also allows the drive system 105 to be connected in parallel with another instance of the drive system 105. The configuration of the drive system 105 allows a customizable drive that reduces or eliminates non-value-adding engineering, manufacturing, field installation, and/or maintenance costs while also achieving optimum power-density and physical dimensions.

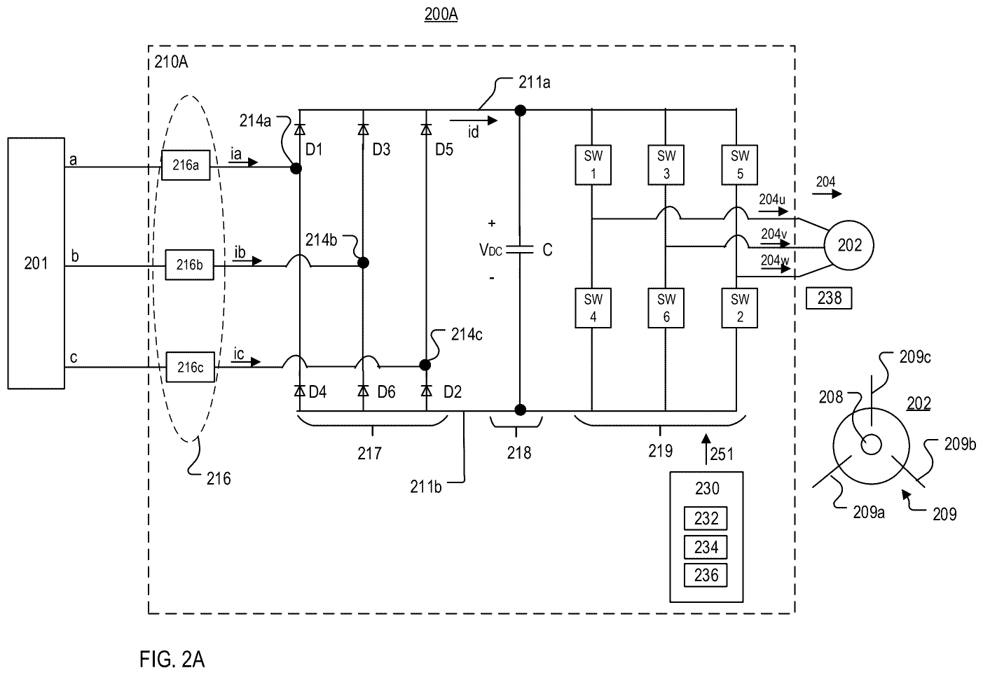

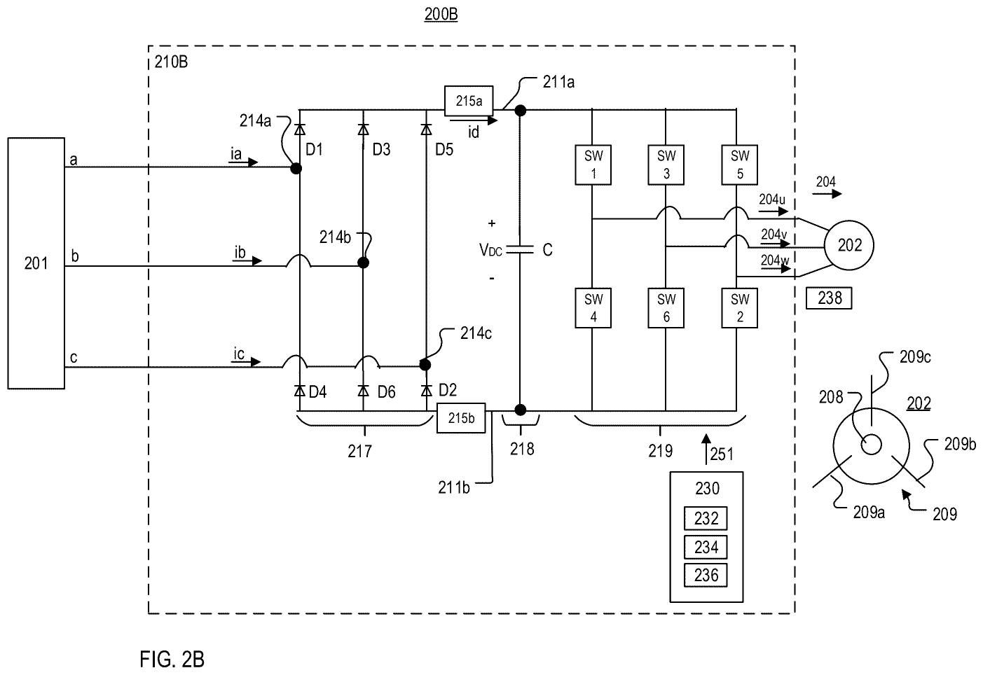

The drive system 105 includes a power converter 110 mounted to a support 120. The power converter 110 may be, for example, an adjustable speed drive (ASD), a variable frequency drive (VFD), or a variable speed drive (VSD). The power converter 110 produces a time-varying or AC drive signal that may be used to drive a load, such as a motor. The power converter 110 may include a rectifier, a DC link, and an inverter, such as shown in FIG. 2. The drive system 105 may be used in a commercial, industrial, municipal, or industrial setting. For example, the drive system 105 may be used to drive a load that is part of a heating, ventilation, and air conditioning/refrigeration (HVAC/R) system; a water treatment facility; a fossil fuel extraction or refining process; a materials handling process; a conveying process; or a power plant, just to name a few.

The support 120 is a three-dimensional object that is capable of supporting the power converter 110 and the other components of the drive system 105. The support 120 is made of a durable and rugged material. Examples of materials that may be used for the support 120 include, without limitation, stainless steel, galvanized steel, or a rugged polymer. Moreover, the support 120 may be a collection of parts that are joined together by, for example, welding. For example, the support 120 may be made out of five parts of sheet metal, all formed separately and assembled together to create the structure to fit and support all the components of the drive system 105. The busbars of the busbar assembly 170 may be electrically insulated from the support 120. For example, an electrically insulating material such as fiberglass may be positioned between the support 120 and the busbars of the busbar assembly 170.

The support 120 is multi-sided. In the example of FIG. 1A, the support 120 is a parallelepiped with six sides, including a side 122 that extends generally in the X-Z plane and a side 123 that extends generally in the Y-Z plane. The side 122 has a width 122w (the extent in the X direction in FIG. 1A), and the side 123 has a width 123w (the extent in the Y direction in FIG. 1A). The width 122w is less than the width 123w.

The drive system 105 includes a first input section 140 on the side 122, a second input section 142 on the side 123, a first output section 144 on the side 122, and a second output section 146 on the side 123. The busbar assembly 170 includes an input busbar 171 that electrically connects the first input section 140 and the second input section 142, a rectifier busbar 173 that electrically connects the input sections 140 and 142 to the power converter 110, an inverter busbar 174 that electrically connects the power converter 110 to the output section(s) 144 and 146, and a drive system output busbar 175 that electrically connects the output sections 144 and 146. Each busbar 171, 173, 174, 175 is an electrically conductive connection of any type. For example, each busbar 171, 173, 174, 175 may be a strip, bar, or wire of an electrically conductive material. Examples of electrically conductive materials that may be used for the busbars 171, 173, 174, 175 include, without limitation, metals such as copper, gold, and/or silver, and metal alloys such as brass.

The drive system 105 is configured to be wall mounted or floor mounted. FIGS. 1B and 1C are side views of a facility 103 in which the drive system 105 may be installed. The facility 103 includes a wall 190, a floor 196, and a cabinet 195 that rests on the floor 196. The drive system 105 may be mounted on the wall 190 or may be floor mounted in the cabinet 195.

To wall-mount the drive system 105, the support 120 is rotated about the Z axis such that a side 124 (which is opposite the side 123) faces a wall 190 and the side 123 faces away from the wall 190. The drive system 105 is moved along the arrow A1 to mount the side 124 to the wall 190 at a mounting point 191. The mounting point 191 holds the drive system 105 to the wall 190. When mounted to the wall 190, the second input section 142 and the second output section 146 also face away from the wall 190 and the drive system 105 does not touch the floor 196. The second input section 142 is accessible to, for example, a human operator that stands on the floor 196 such that the second input section 142 may be easily connected to an AC source, and the second output section 146 is accessible and may be easily connected to a load.

To use the drive system 105 in a floor-mounted configuration, the support 120 is rotated about the Z axis until the drive system 105 is aligned with the cabinet 195 with a side 125 (which is opposite the side 122) facing into the cabinet 195. The drive system 105 is moved along the arrow A2 and placed in the cabinet 195 with the side 122, the first input section 140, and the first output section 144 facing out of the cabinet 195. The first input section 140 is accessible and may be easily connected to an AC source, and the first output section 144 is accessible and may be easily connected to a load.

Legacy drive systems are configured for wall mounting or floor mounting, but not both. Drive systems may be rated based on power output in units of horsepower (HP). Low-power to medium-power legacy drive systems (for example, legacy drive systems with ratings below 350 HP) are generally designed as wall-mountable units. High-power legacy drive systems (for example, legacy drive systems with ratings equal to or above 350 HP) are heavier and wider than low-power and medium-power drive systems. The extra weight and width results in size and installation constraints that make wall mounting impractical or impossible for legacy high-power drives. Moreover, legacy high-power drive systems typically have a completely different design than low-power or medium-power drive systems and require different installation equipment and a different volume of space.

On the other hand, the dimensions of the support 120, the placement of the input sections 140, 142, and the placement of the output sections 144, 146 allow the drive system 105 to be wall mounted or floor mounted. This flexible approach and design achieves cost savings in installation, maintenance, distribution, and manufacturing. For example, because the same drive system 105 may be wall mounted or floor mounted, the end-user has more options for placement and may more efficiently use the space available in their facility. Additionally, manufacturing efficiency is improved because one assembly (the drive system 105) may be used for wall-mounted and floor-mounted applications. Furthermore, inventory management and supply chain efficiencies are also achieved because one type of assembly (the drive system 105) is stored and shipped for floor-mounted and wall-mounted applications.

Additionally, this configuration provides more options for the drive system 105 to be used in existing enclosures. For example, the drive system 105 may be a high-power design that has a larger than typical width 123w that is too wide to fit into a standard or existing industrial enclosure but a depth 122w that is smaller than the width 123w. By having the option to rotate the drive system 105 90° about the Z axis, the drive system 105 is able to fit into the existing enclosure.

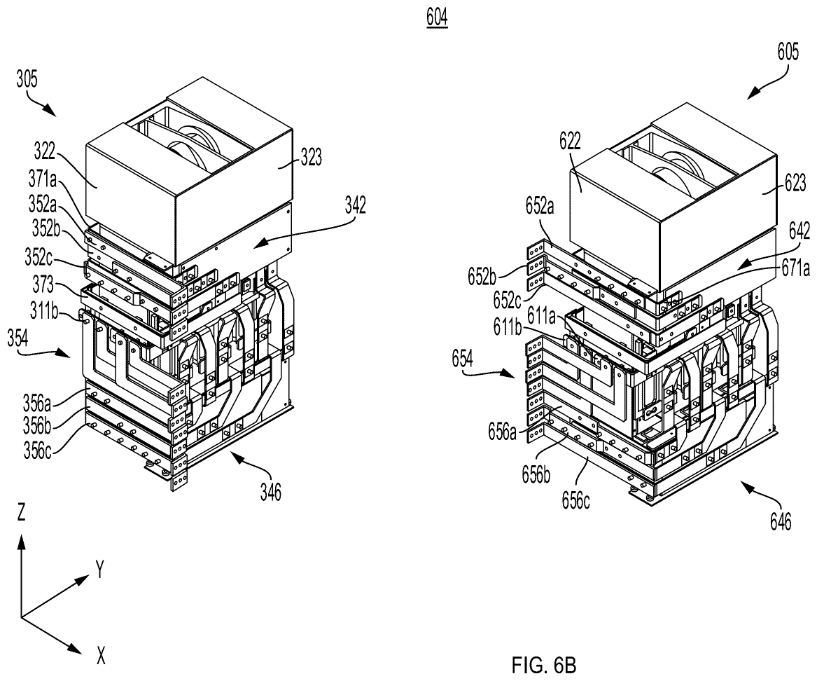

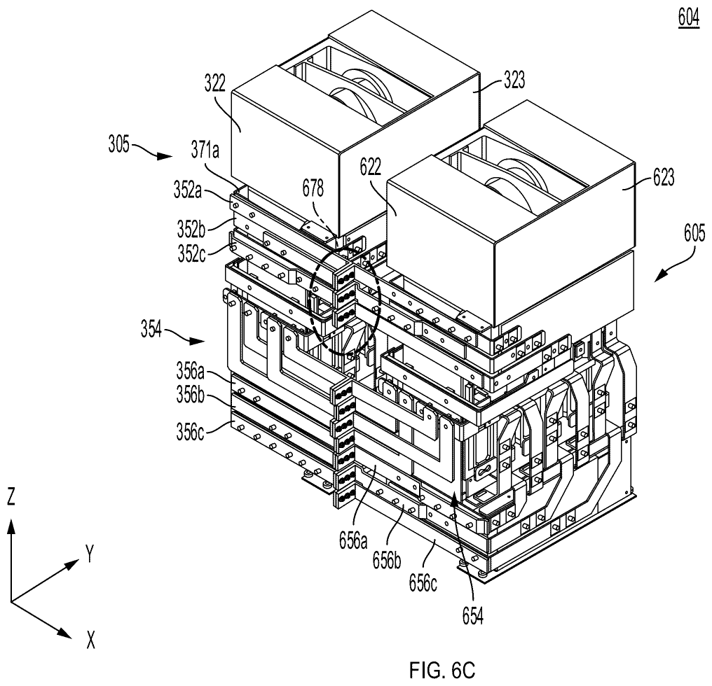

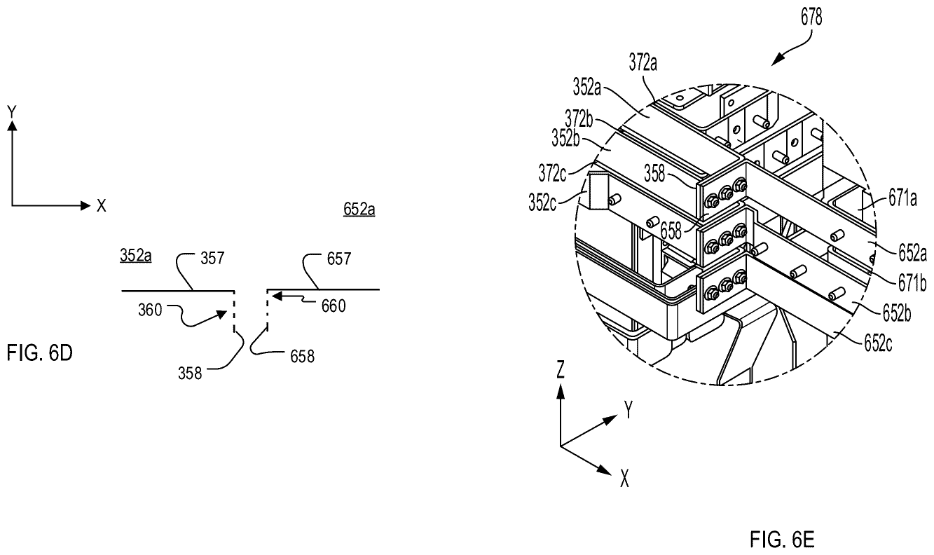

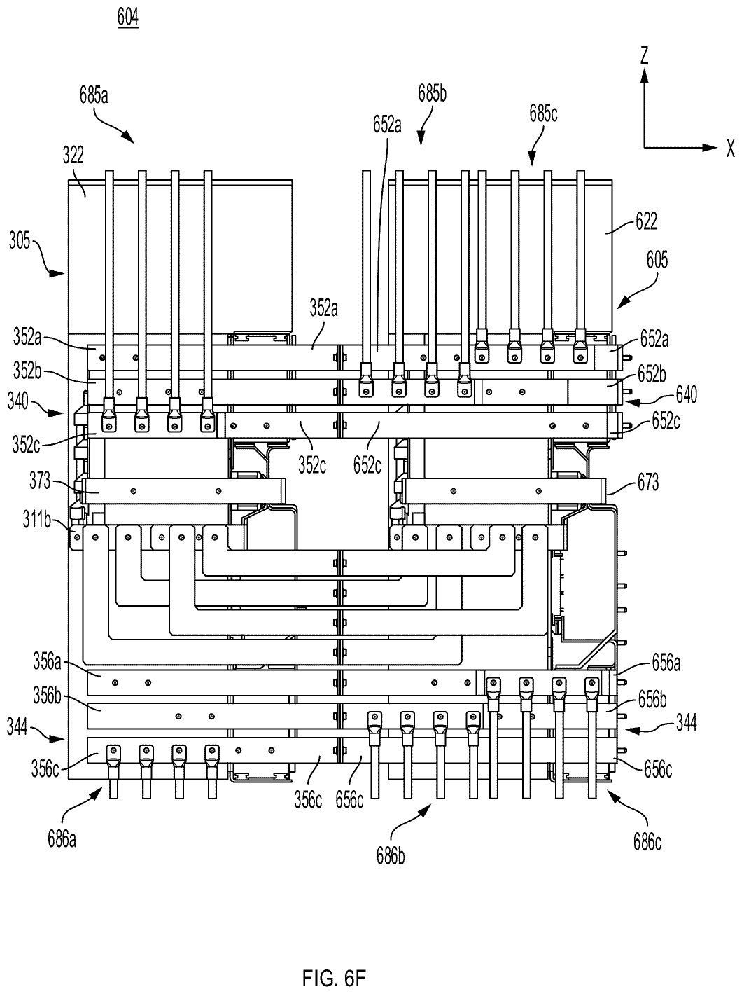

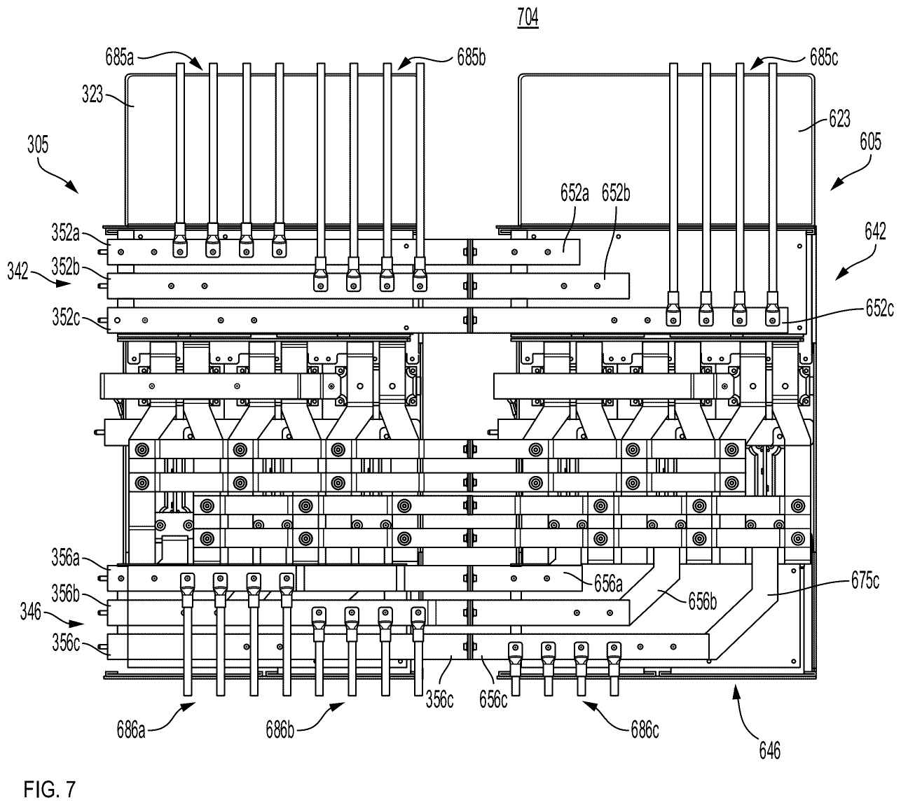

The support 120 is compact and robust, providing space savings as compared to a legacy drive system having the same power rating. The support 120 is also easier to maintain and service. Moreover, the drive system 105 is a modular unit that may be electrically connected in parallel with other instances of the drive system 105. FIGS. 6F and 7 show examples of paralleled drive systems.

FIG. 2A is a schematic of a system 200A. The system 200A includes an electrical apparatus 210A that connects to a three-phase electrical power distribution network 201. The electrical apparatus 210A may be a power converter that includes a rectifier 217, a DC link 218, and an inverter 219. The inverter 219 provides a three-phase driver signal 204 to a motor 202. A control system 230 generates a switching command 251 that controls the inverter 219 to generate the three-phase driver signal 204. The switching command 251 operates the controllable switches SW1 to SW6 in a particular pattern to generate a target or reference inverter output voltage. The control system 230 may use a pulse width modulation (PWM) technique to generate the switching command 251.

In the example of FIG. 2A, the load 202 is a three-phase motor 202, such as, for example, an induction motor or a permanent magnet synchronous machine. The motor 202 includes a stator 209, which is spatially fixed, and a rotor 208, which rotates relative to the stator 209 when the driver signal 204 is applied. The stator 209 includes one electrical winding per phase: 209a, 209b, and 209c. Loads other than a motor may be used in the system 200.

The electrical power distribution network 201 distributes AC electrical power that has a fundamental frequency of, for example, 50 or 60 Hertz (Hz). The distribution network 201 may have an operating voltage of up to 690V. In some implementations, the distribution network 201 has an operating voltage greater than 690V. The distribution network 201 may include, for example, one or more transmission lines, distribution lines, electrical cables, and/or any other mechanism for transmitting electricity. The distribution network 201 includes three phases, which are referred to as a, b, and c.

The rectifier 217 is a three-phase six-pulse bridge that includes six electronic switches. In the example of FIG. 2A, the six electronic switches are diodes D1, D2, D3, D4, D5, and D6 (referred to as diodes D1 to D6). Each diode D1 to D6 includes a cathode and an anode and is associated with a forward bias voltage. Each diode D1 to D6 allows current to flow in the forward direction (from the anode to the cathode) when voltage of the anode is greater than the voltage of the cathode by at least the bias voltage. When the voltage difference between the anode and the cathode is less than the forward bias voltage, the diode does not conduct current in the forward direction.

The electrical apparatus 210A includes input nodes 214a, 214b, 214c, each of which is electrically coupled to a respective one of the three phases a, b, c of the distribution network 201. The electrical apparatus 210A also includes a filter system 216 that includes inductors 216a, 216b, 216c. The inductor 216a is between the input node 214a and phase a of the electrical power distribution network 201. The inductor 216b is between the input node 214b and phase b of the electrical power distribution network 201. The inductor 216c is between the input node 214c and phase c of the electrical power distribution network 201. The filter system 216 may be referred to as an AC inductor filter or an AC inductor. Other implementations are possible. For example, and as shown in FIG. 2B, a DC choke may be used instead of the filter system 216.

The input node 214a is electrically connected to the anode of the diode D1 and the cathode of the diode D4. The input node 214b is electrically connected to the anode of the diode D3 and the cathode of the diode D6. The input node 214c is electrically connected to the anode of the diode D5 and the cathode of the diode D2. The diodes D1 to D6 rectify the input currents ia, ib, ic into a DC current id.

The diodes D1 to D6 are also electrically connected to the DC link 218. The cathode of each diode D1, D3, D5 is electrically connected to a positive DC bus 211a that is electrically connected to the DC link 218, and the anode of each diode D2, D4, D6 is electrically connected to a negative DC bus 211b that is electrically connected to the DC link 218. The DC link 218 includes a capacitor network C. The capacitor network C includes one or more capacitors that store electrical energy when the rectified current id flows from the rectifier 217 and discharge the stored electrical energy when the rectified current id does not flow from the rectifier 217.

The inverter 219 converts the DC power stored in the capacitor network C into a three-phase AC driver signal 204 that is provided to the load 202. The inverter 219 includes a network of electronic switches SW1, SW2, SW3, SW4, SW5, and SW6 (referred to as switches SW1 to SW6) that are controlled by the control system 230 to generate the driver signal 204. Each of the switches SW1 to SW6 may be, for example, a power transistor. The three-phase driver signal 204 has phase components 204u, 204v, 204w, each of which is provided to one of the three phases of the load 202.

The control system 230 generates the switching command 251, which controls the switching pattern of the switches SW1 to SW6 to generate the driver signal 204 with particular characteristics (for example, amplitude, frequency, and/or phase). The control system 230 includes an electronic processing module 232, an electronic storage 234, and an input/output (I/O) interface 236. The electronic processing module 232 includes one or more electronic processors. The electronic processors of the module 232 may be any type of electronic processor and may or may not include a general purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 234 may be any type of electronic memory that is capable of storing data and instructions in the form of computer programs or software, and the electronic storage 234 may include volatile and/or non-volatile components. The electronic storage 234 and the processing module 232 are coupled such that the processing module 232 is able to access or read data from and write data to the electronic storage 234. The electronic storage 234 stores instructions that, when executed, cause the electronic processing module 232 to analyze data and/or retrieve information. The electronic storage 234 also may store information about the system 200. For example, the electronic storage 234 may store information about the motor 202 or the inverter 219. Additionally, the electronic storage 234 may store executable instructions that implement a PWM technique for generating the switching command 251.

The I/O interface 236 may be any interface that allows a human operator and/or an autonomous process to interact with the control system 230. The I/O interface 236 may include, for example, a display (such as a liquid crystal display (LCD)), a keyboard, audio input and/or output (such as speakers and/or a microphone), visual output (such as lights, light emitting diodes (LED)) that are in addition to or instead of the display, serial or parallel port, a Universal Serial Bus (USB) connection, and/or any type of network interface, such as, for example, Ethernet. The I/O interface 236 also may allow communication without physical contact through, for example, an IEEE 802.11, Bluetooth, or a near-field communication (NFC) connection. The control system 230 may be, for example, operated, configured, modified, or updated through the I/O interface 236.

The I/O interface 236 also may allow the control system 230 to communicate with components in the system 200 and with systems external to and remote from the system 200. For example, the I/O interface 236 may control a switch or a switching network (not shown) or a breaker within the system 200 that allows the electrical apparatus 210A to be disconnected from the distribution network 201. In another example, the I/O interface 236 may include a communications interface that allows communication between the control system 230 and a remote station (not shown), or between the control system 230 and a separate monitoring apparatus. The remote station or the monitoring apparatus may be any type of station through which an operator is able to communicate with the control system 230 without making physical contact with the control system 230. For example, the remote station may be a computer-based work station, a smart phone, tablet, or a laptop computer that connects to the control system 230 via a services protocol, or a remote control that connects to the control system 230 via a radio-frequency signal.

Other implementations are possible. For example, the rectifier 217 is shown as a diode-bridge front end based configuration. However, the rectifier 217 may have another configuration. For example, the rectifier 217 may be a hybrid diode-thyristor rectifier, a motor drive, or an active front end that includes six transistors or other controllable switches instead of the diodes D1 to D6.

In another example, and referring to FIG. 2B, which is a schematic of another power converter 210B, a DC choke may be used instead of the filter system 216. The DC choke includes an inductor 215a in the positive DC bus 211a between the rectifier 217 and the DC link 218, and an inductor 215b in the negative DC bus 211b between the rectifier 217 and the DC link 218. The inductors 215a, 215b may be in any configuration. For example, the inductors 215a, 215b may be separate inductors, as shown in FIG. 2B. In some implementations, the inductors 215a, 215b may be integrated on a common magnetic core.

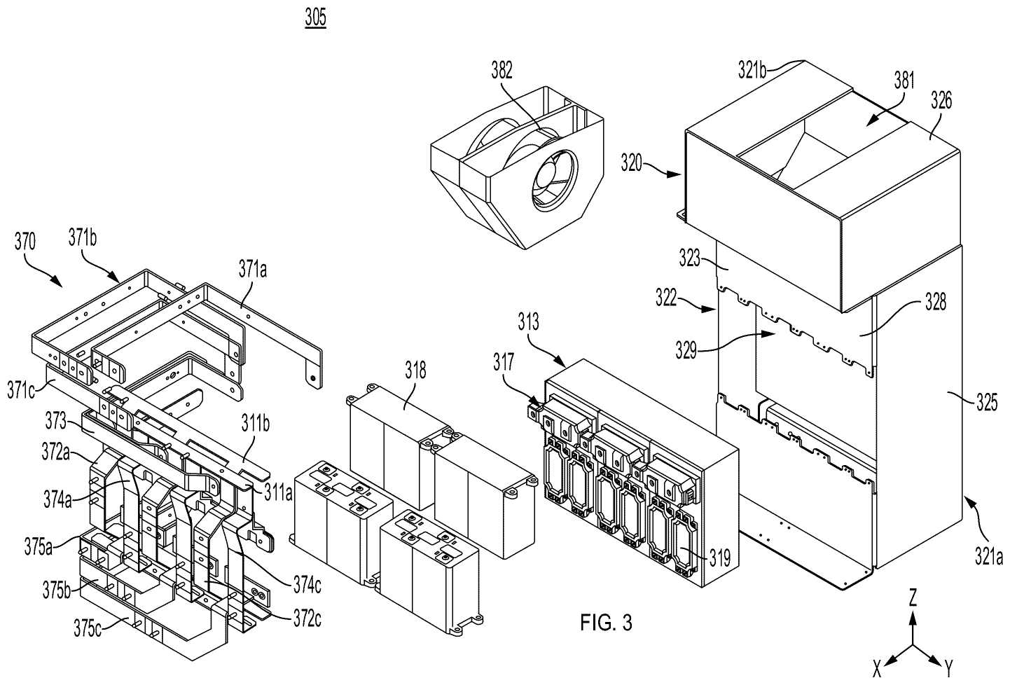

FIG. 3 is an exploded perspective view of a three-phase drive system 305. The three-phase drive system 305 includes a fan assembly 382, a capacitor system 318, an inverter 319, a busbar assembly 370, a rectifier system 317, and a heat sink assembly 313.

The three-phase drive system 305 also includes a structure 320. The structure 320 is made of a durable material such as, for example, stainless steel or galvanized steel. The structure 320 is a multi-sided object that is generally a parallelepiped. The structure 320 includes a lower portion 321a and an upper portion 321b.

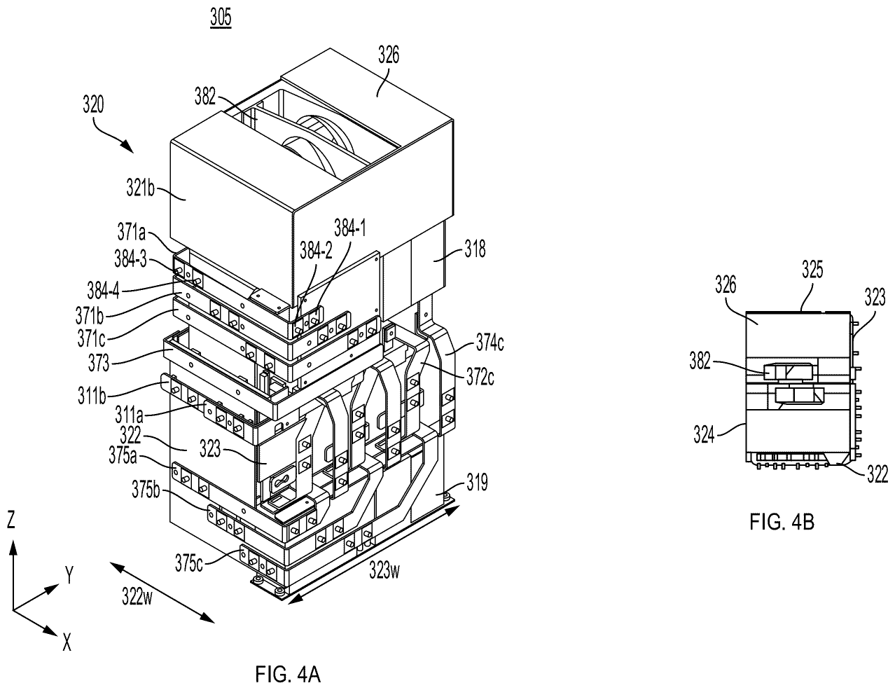

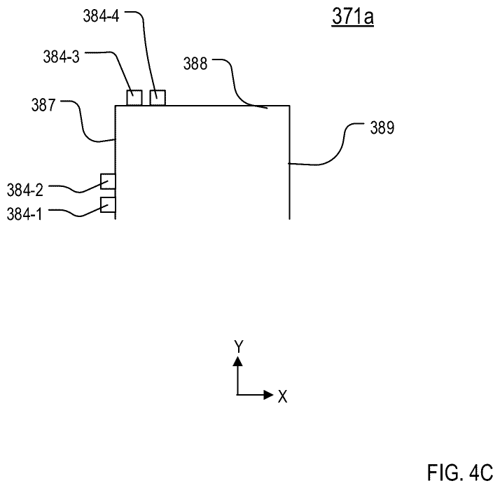

The lower portion 321a includes a side 323 with a planar surface 328 that generally extends in the Y-Z plane and defines a recessed region 329. The side 323 has an extent of 323w (labeled in FIG. 4A) in the Y direction. The recessed region 329 extends into the structure in the −X direction. The recessed region 329 receives and holds the rectifier system 317. The lower portion 321a also includes a side 325 that extends in the X-Z plane and a side 322 that is opposite and parallel to the side 325. The side 322 has an extent of 322w (labeled in FIG. 4A) in the X direction. The upper portion 321b includes a recessed region 381 formed in a top side 326 of the structure 320. The recessed region 381 extends into the upper portion 321a in the −Z direction. The recessed region 381 holds the fan assembly 382.

The busbar assembly 370 includes a plurality of busbars that are, for example, electrically conductive bars, rods, or strips. The busbars of the busbar assembly 370 are made of any electrically conductive material, such as, for example, copper, gold, aluminum, brass, or a metal alloy. The busbar assembly 370 includes input busbars 371a, 371b, 371c; three rectifier busbars 373a, 373b, 373c (labeled collectively as 373 in FIG. 3); a positive DC busbar 311a, a negative DC busbar 311b, negative inverter busbars 372a, 372b, 372c; positive inverter busbars 374a, 374b, 374c; and output busbars 375a, 375b, 375c.

To assemble the drive system 305, the rectifier module 317 is inserted into the recessed region 329. The capacitor system 318 is attached to the side 323 of the structure 320 above the rectifier module 317. The inverter 219 is attached to the side 323 of the structure 320 below the rectifier module 317. The fan assembly 382 is inserted into the recessed region 381.

FIGS. 4A and 4B show the three-phase drive system 305 in an assembled state. FIG. 4A is a perspective view of the three-phase drive system 305. FIG. 4B shows the top side 326 of the drive system 305. Each input busbar 371a, 371b, 371c is substantially U-shaped or a partial rectangle and is attached to the sides 322, 323, and 324 of the structure 320. Referring also to FIG. 4C, which shows the input busbar 371a in the X-Y plane while not attached to the structure 320, the input busbar 371a includes a first portion 387, a second portion 388, and a third portion 389. The first and third portions 387 and 389 are parallel to each other and extend in the same direction from the second portion 388. The second portion 388 is perpendicular to the first and third portions 387 and 389, and the second portion 388 has an extent that is slightly more than the extent 322w of the side 322. The first and third portions 387 and 389 are no longer than the extent 323w of the side 323. Although the first and third portions 387 and 389 are shown as having substantially the same length in the Y direction, this is not necessarily the case, and the first portion 387 may be longer or shorter than the third portion 389.

The input busbar 371a also includes electrical connection points 384-1, 384-2, 384-3, and 384-4. The connection points 384-1 and 384-2 extend in the −X direction from the first portion 387, and the connection points 384-3 and 384-4 extend in the Y direction from the second portions 388. The electrical connection points 384-1, 384-2, 384-3, and 384-4 allow an external device to be electrically connected to the input busbar 371a. The connection points 384-1, 384-2, 384-3, and 384-4 are any kind of electrically conductive element that may be used in an electrical connection. For example, the connection points 384-1, 384-2, 384-3, and 384-4 may be metallic bolts or posts that extend perpendicularly from the input busbar 371a. The connection points 384-1, 384-2, 384-3, and 384-4 may be an integral part of the input busbar 371a or may be separate elements that are in physical contact with the input busbar 371a.

Referring again to FIG. 4A, when the input busbar 371a is attached to the structure 320, the second portion 388 and the electrical connection points 384-3 and 384-4 are on the side 322. The first portion 387 and the electrical connection points 384-1 and 384-2 are on the side 323.

The positioning of the electrical connection points 384-1, 384-2, 384-3, and 384-4 on different portions of the input busbar 371a encourages efficient use of the drive system 305. The electrical connection points 384-3 and 384-4 are accessible when the drive system 305 is used with the side 322 facing outward (such as in the floor-mounted configuration shown in FIG. 1C). The electrical connection points 384-1 and 384-2 are accessible when the drive system 305 is used with the side 323 facing outward (such as in the wall-mounted configured configuration shown in FIG. 1B).

The input busbars 371b, 371c and output busbars 375a, 375b, 375c also include electrical connection points on more than one side or portion. In the example of FIG. 4A, when the drive system 305 is assembled, each input busbar 371b and 371c has two electrical connection points on the side 322 and two electrical connection points on the side 323. The electrical connection points on the input busbars 371a, 371b, 371c that are on the side 322 are part of a first input section. The electrical connection points on the input busbars 371a, 371b, 371c that are on the side 323 are part of a second input section.

Each output busbar 375a, 375b, 375c also has two electrical connection points on the side 322 and two electrical connection points on the side 323. The electrical connection points on the output busbars 375a, 375b, 375c that are on the side 322 are part of a first output section. The electrical connection points on the output busbars 375a, 375b, 375c that are on the side 323 are part of a second output section. When the drive system 305 is mounted with the side 322 facing outward (such as in a floor-mounted configuration), the first input section and the first output section also face outward. When the drive system 305 is mounted with the side 323 facing outward (such as in a wall-mounted configuration), the second input section and the second output section face outward. In this way, the drive system 305 is easily used in two mounting configurations.

The other busbars in the busbar assembly 370 also may include electrical connection points. Moreover, the input busbars 371a, 371b, 371c may have other forms. For example, each input busbar 371a, 371b, 371c may be L-shaped and attached to the sides 322 and 323 of the structure 320.

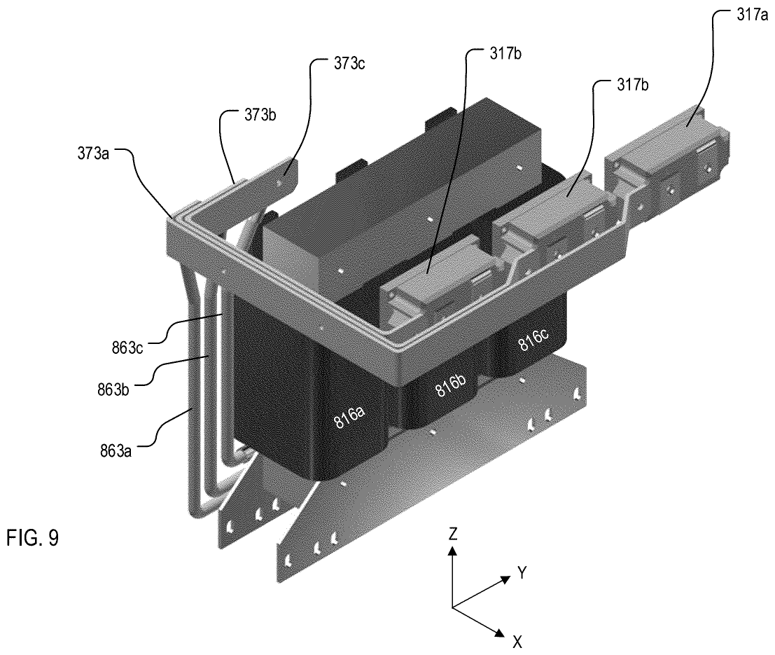

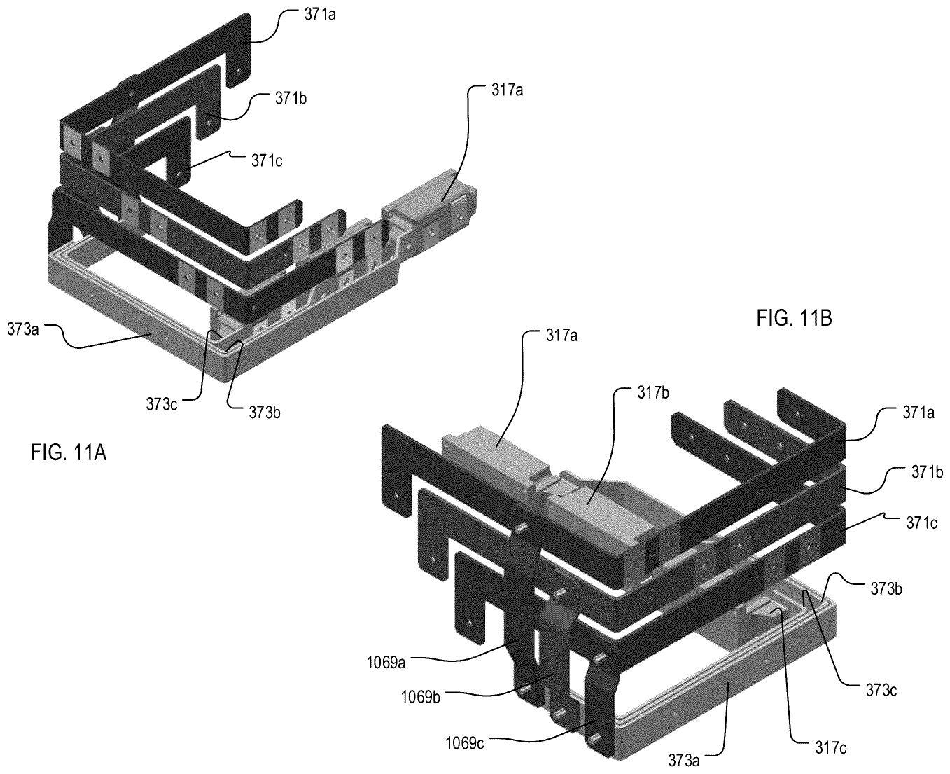

When the drive system 305 is assembled, each input busbar 371a, 371b, 371c is electrically connected to one phase of the rectifier module 317 with one of the rectifier busbars 373. Examples of the connection with the rectifier busbars 373 are shown in FIGS. 9, 11A, and 11B. The rectifier module 317 is electrically connected to the capacitor system 318. The capacitor system 318 is electrically connected to the DC busbars 311a, 311b. The DC busbar 311a is electrically connected to the inverter 319 through the positive inverter busbars 374a, 374b, 374c and the DC busbar 311b is electrically connected to the inverter through the negative inverter busbars 372a, 372b, 372c. Each output busbar 375a, 375b, 375c is electrically connected to one phase of the output of the inverter 319.

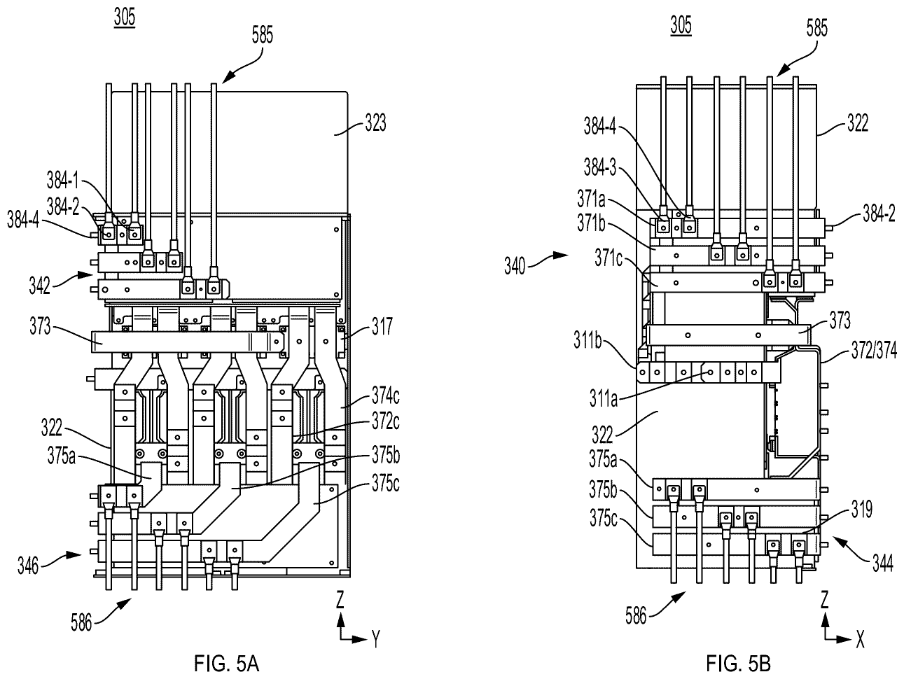

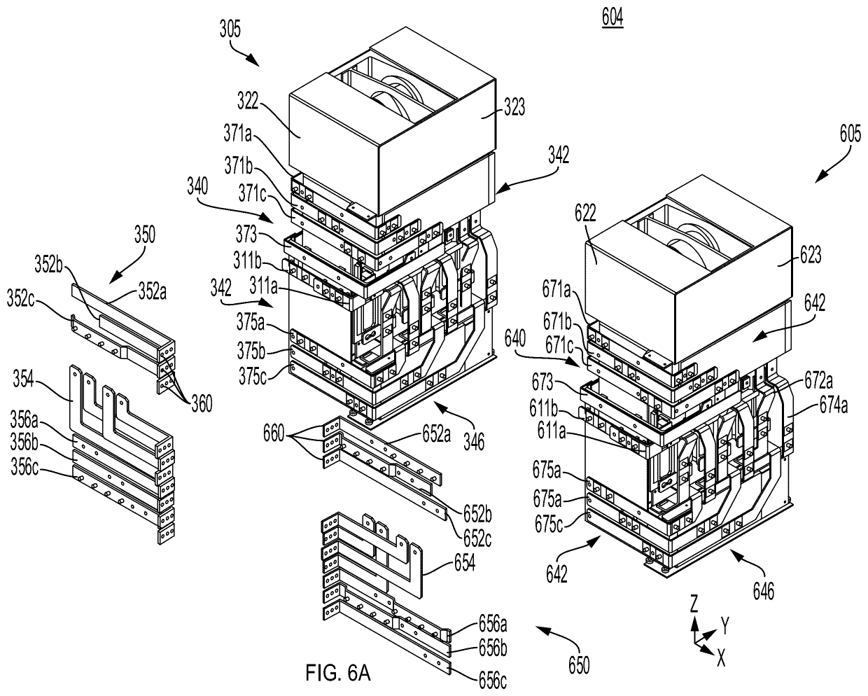

FIGS. 5A and 5B show the drive system 305 connected to cables 585, which may be electrically connected to a first external electrical device (for example, the grid 201), and cables 586, which may be electrically connected to a second external electrical device (for example, the motor 202). FIG. 5A shows the side 323 of the assembled drive system 305. FIG. 5B shows the side 322 of the assembled drive system 305.

The electrical connection points on the input busbars 371a, 371b, 371c on the side 322 are a first input section 340, and the electrical connection points on the input busbars 371a, 371b, 371c on the side 323 are a second input section 342. The electrical connection points on the output busbars 375a, 375b, 375c on the side 322 are a first output section 344, and the electrical connection points on the output busbars 375a, 375b, 375c on the side 323 are a second input section 342.

Referring to FIG. 5A, to use the drive system 305 with the side 323 facing outward (such as in a wall-mounted configuration), the cables 585 are electrically connected to electrical connection points in the second input section 342 and the cables 586 are electrically connected to the electrical connection points in the second output section 346. Referring to FIG. 5B, to use the drive system 305 with the side 322 facing outward (such as in a floor-mounted configuration), the cables 585 are connected to the first input section 340 and the cables 586 are connected to the first output section 344.

The drive system 305 may be connected in parallel with one or more identical drive systems. FIGS. 6A-6F show various views of a paralleled drive system 604. The paralleled drive system 604 includes the drive system 305 and a drive system 605 that is identical to the drive system 305. In the example of FIGS. 6A-6F, the drive system 305 and the drive system 605 are in the cabinet-mounted configuration.

The drive system 605 includes a support 620 that includes sides 622 and 623, and a busbar assembly 670 that is configured in the same manner as the busbar assembly 370. The busbar assembly 670 includes input busbars 671a, 671b, 671c; three rectifier busbars 673 (only one is labeled); a positive DC busbar 611a, a negative DC busbar 611b, negative inverter busbars 672a, 672b, 672c; positive inverter busbars 674a, 674b, 674c; and output busbars 675a, 675b, 675c. The drive system 605 also includes a first input section 640, a second input section 642, a first output section 644, and a second output section 646. The first input section 640 and the first output section 644 are on the side 622. The second input section 642 and the second output section 646 are on the side 623.

The paralleled drive system 604 also includes a first busbar subassembly 350, and a second busbar subassembly 650. Each busbar subassembly 350, 650 includes a plurality of electrically conductive busbars. The busbar subassembly 350 includes input connection busbars 352a, 352b, 352c; four DC connection busbars 354, and output connection busbars 356a, 356b, 356c. The busbar subassembly 650 includes input connection busbars 652a, 652b, 652c; DC connection busbars 654, and output connection busbars 656a, 656b, 656c.

Referring also to FIG. 6B, to prepare the drive system 305 to be electrically connected to the drive system 605, the input connection busbar 352a is mounted to the input busbar 371a, the input connection busbar 352b is mounted to the input busbar 371b, and the input connection busbar 352c is connected to the input busbar 371c. The output connection busbar 356a is mounted to the output busbar 375a, the output connection busbar 356b is mounted to the output busbar 375b, and the output connection busbar 356c is mounted to the output busbar 375c. Two of the DC connection busbars 354 are mounted to the positive DC busbar 311a, and two of the DC connection busbars 354 are mounted to the negative DC busbar 311b.

To prepare the drive system 605 to be electrically connected to the drive system 305, the input connection busbar 652a is connected to the input busbar 671a, the input connection busbar 652b is connected to the input busbar 671b, and the input connection busbar 652c is connected to the input busbar 671c. The output connection busbar 656a is connected to the output busbar 675a, the input connection busbar 656b is connected to the output busbar 675b, and the output connection busbar 656c is connected to the output busbar 675c. Two of the DC connection busbars 654 are connected to the positive DC busbar 611a, and two of the DC connection busbars 654 are connected to the negative DC busbar 611b.

Each busbar in the subassembly 305 is mounted to one of the busbars of the drive system 305 any way that provides an electrical connection between mounted busbars. For example, the input busbar 371a includes posts or bolts that extend in the −Y direction, and the input connection busbar 352a includes openings, each of which is sized to receive one of the posts or bolts on the input busbar 371a. To mount the input connection busbar 352a to the input busbar 371a, the input connection busbar 352a is positioned in contact with the input busbar 371a with each opening on the input connection busbar 352a receiving one of the posts or bolts. The input connection busbar 352a may be further secured to the input busbar 371a by placing a nut or other fastening device over each post or bolt after the input connection busbar 352a is placed on the input busbar 371. The input connection busbar 352a may be removed from the input busbar 371a without damaging the input connection busbar 352a or the input busbar 371a.

The other busbars in the subassembly 350 and the busbars in the subassembly 650 are mounted to a busbar of the drive system 305 or the drive system 605 in a similar manner.

Referring also to FIG. 6C, after the subassembly 350, 650 is mounted to the respective drive system 305, 605, the subassemblies 350 and 650 are electrically connected to each other to form the paralleled drive system 604. Specifically, each input connection busbar 352a, 352b, 352c is connected to the respective input busbar 652a, 652b, 652c of the drive system 605; each DC connection busbar 354 is connected to one of the corresponding DC connection busbars 654; and each output connection busbar 356a, 356b, 356c is connected to the respective output busbar 656a, 656b, 656c of the drive system 605.

The physical connection between the subassembly 305 and the subassembly 605 is discussed further with respect to FIGS. 6D and 6E. FIG. 6D is a top cross-sectional view in the X-Y plane of the input connection busbar 352a when it is not mounted to the input busbar 371a and the input connection busbar 652a when it is not mounted to the input busbar 671a. The input connection busbar 352a includes a first portion 357 and a second portion 358 that extends perpendicularly from an end of the first portion 357. The first portion 357 and the second portion 358 are perpendicular to each other. The second portion 358 includes mounting points 360. The input connection busbar 652a includes a first portion 657 and a second portion 658 that extends perpendicularly from the first portion 657. The second portion 658 includes mounting points 660.

The mounting points 360 and 660 are any kind of device or feature that allows the input connection busbar 352a to physically and electrically connect to the input connection busbar 652a. For example, the mounting points 330 and the mounting points 660 may be openings in the respective second portions 358 and 658 through which a metallic bolt or pin may pass. In another example, the mounting points 330 may be metallic posts and the mounting points 630 may be openings that receive and hold the metallic posts.

The other busbars in the subassembly 350 and the busbars in the subassembly 650 are configured in a similar manner and include at least a first portion and a second portion that extends perpendicularly form the first portion, where the second portion includes mounting points.

FIG. 6E shows a detailed view of the inset 678 of FIG. 6C. The inset 678 includes the input connection busbars 352a, 352b, 352c when connected to the input connection busbars 652a, 652b, 652c. The connection points 330 are openings in the second portions of the input connection busbars 352a, 352b, 352c and the connection points 630 are openings in the second portions of the input connection busbars 652a, 652b, 652c.

The input connection busbars 352a, 352b, 352c are connected to the input connection busbars 652a, 652b, 652c by aligning each of the openings 360 with a corresponding one of the openings 630 and then passing a bolt through each pair of aligned openings 360, 660. Each bolt is fastened with a nut.

FIG. 6F shows the paralleled cabinet-mounted system 608 in the X-Z plane when connected to input phase cables 685a, 685b, 685c and output phase cables 686a, 686b, 686c. The input phase cables 685a are electrically connected to the input connection busbar 352c, which is electrically connected to the input busbar 371c (labeled in FIG. 6A). The input phase cables 685b are electrically connected to the input connection busbar 652b, which is electrically connected to the input busbar 671b (labeled in FIG. 6A). The input phase cables 685c are electrically connected to the input connection busbar 652a, which is electrically connected to the input busbar 671a (labeled in FIG. 6A). The input phase cables 685a, 685b, 685c also may be connected to the first, second, and third phases of an external source (not shown in FIG. 6F). The output phase cables 686a, 686b, 686b are electrically connected to the output connection busbar 356c, 656b, 656a, respectively. Each of the output phase cables 686a, 686b, 696c also may be connected to one phase of a three-phase load, such as a motor. In this way, the drive systems 305 and 605 are electrically connected in parallel and are used together to drive a load.

FIGS. 6A-6F relate to an example in which the drive systems 305 and 605 are connected in parallel in the cabinet-mounted configuration. However, the subassemblies 350 and 650 may be used to connect the drive systems 305 and 605 in parallel in the wall-mounted configuration. FIG. 7 is a side view of a paralleled system 704 in which the drive systems 305 and 605 are connected in parallel in the wall-mounted configuration. In the example of FIG. 7, the input phase cables 685a, 685b, 685c are electrically connected to the input connection busbar 352a, the input connection busbar 352b, and the input connection 652c, respectively. The output phase cables 686a, 685b, 685c are electrically connected to the output connection busbar 356a, the output connection busbar 356b, and the output connection busbar 656c, respectively.

Furthermore, although the paralleled drive systems 604 and 704 include two drive systems, more than two drive systems may be connected in parallel. For example, another drive system that is identical to the drive system 305 may be positioned in the cabinet-mounted configuration and connected in parallel with the system 604 with a busbar subassembly that is identical to the busbar subassembly 350. In another example, another drive system that is identical to the drive system 305 may be positioned in the wall-mounted configuration and connected in parallel with the system 705 using a busbar subassembly that is the same as the busbar subassembly 350.

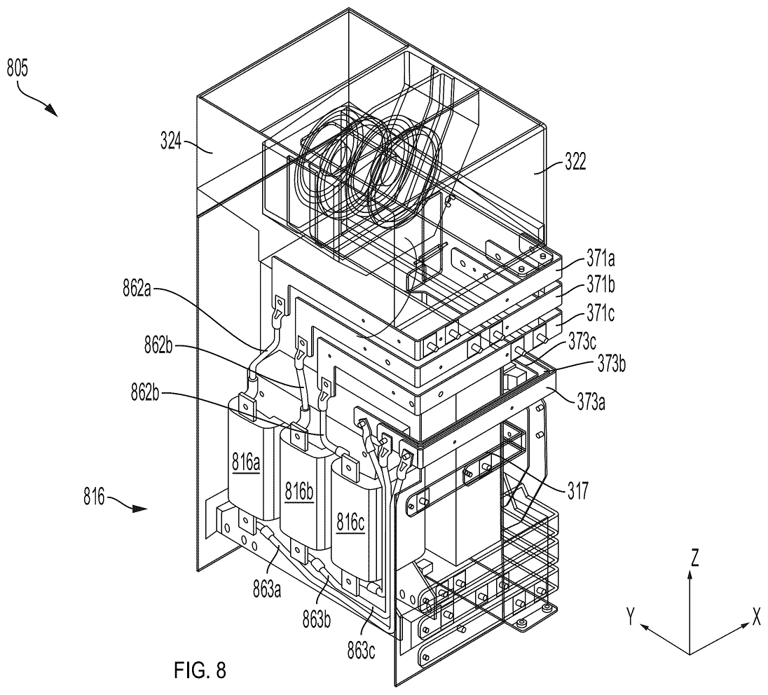

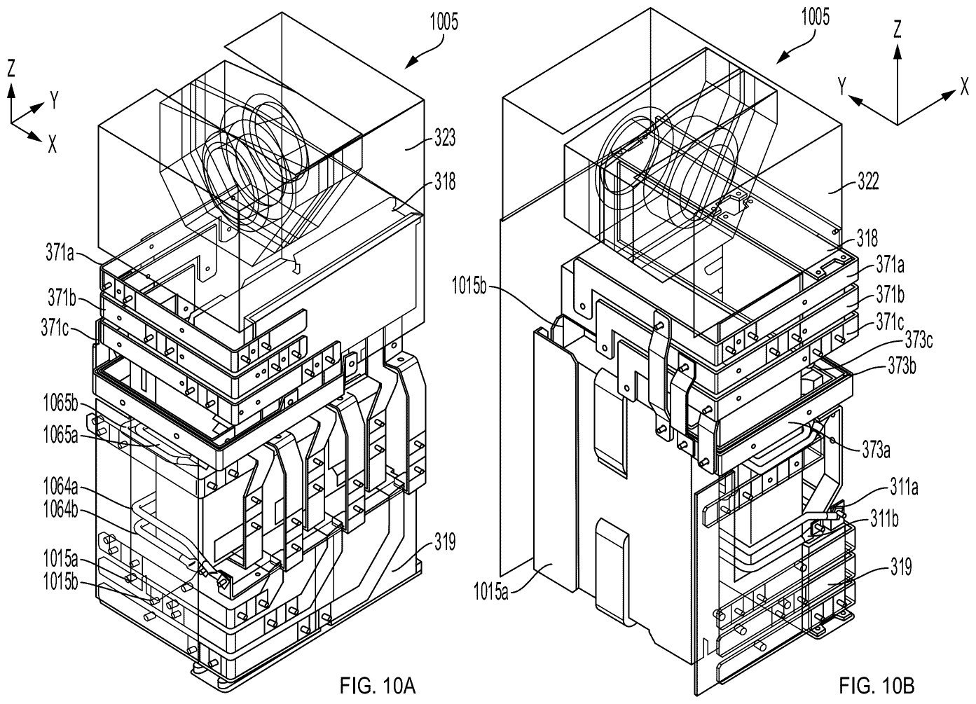

Additionally, the drive system can be configured in the factory to include either a DC choke or an AC inductor to meet the application requirements or specifications of the end-user, distributor, owner, operator, or other entity associated with the drive system. By having the DC choke or AC inductor installed in the drive system at the point of manufacture or assembly, the end-user or other entity associated with the drive system is able to treat the drive system as a black box that is simple and straightforward to install. FIGS. 8 and 9 relate to a drive system with an AC inductor. FIGS. 10A, 10B, 11A, and 11B relate to a drive system with a DC choke.

FIG. 8 is a perspective interior view of another three-phase drive system 805. The drive system 805 is similar to the drive system 305, but the drive system 805 includes an AC inductor system 816 and is an example of a drive system that can be represented schematically as shown in FIG. 2A. The AC inductor system 816 includes three inductors, 816a, 816b, 816c. The AC inductor system 816 is between an input of the drive system 806 and the three-phase rectifier system 317. The AC inductor system 816 is internal to the drive system 805 and is configured by the manufacturer of the drive system 805. The end-user of the drive system 805 does not have to connect the AC inductor system 816 to the drive system 805. Thus, the drive system 805 is simpler to install and use as compared to a system in which the AC inductor is a separate component.

The drive system 805 includes the input busbars 371a, 371b, 371c. The input busbar 371a is electrically connected to the inductor 816a through an electrical connection 862a, the input busbar 371b is electrically connected to the inductor 816b through an electrical connection 862b, and the input busbar 371c is electrically connected to the inductor 816c through an electrical connection 862c. The inductor 816a is electrically connected to the rectifier busbar 373a through an electrical connection 863a, the inductor 816b is electrically connected to the rectifier busbar 373b through an electrical connection 863b, and the inductor 816c is electrically connected to the rectifier busbar 373c through an electrical connection 863c. Any type of electrical connection may be used for the electrical connections 862a, 862b, 862c, 863a, 863b, 863c. For example, the electrical connections 862a, 862b, 862c, 863a, 863b, 863c may be electrically conductive wires, cables, busbars, or conduits.

Referring also to FIG. 9, which is a perspective view of the AC inductor system 816, the rectifier system 317 includes rectifier modules 317a, 317b, 317c. Each rectifier module 317a, 317b, 317c is configured to rectify one phase of a three-phase AC voltage wave. For example, the rectifier module 317a may include two diodes arranged as the diodes D1 and D4 are arranged in FIG. 2A, the rectifier module 317b may include two diodes arranged as the diodes D3 and D6 are arranged in FIG. 2A, and the rectifier module 317c may include two diodes arranged as the diodes D5 and D2 are arranged in FIG. 2A. The rectifier module 317a is electrically connected to the rectifier busbar 373a, the rectifier module 317b is electrically connected to the rectifier busbar 373b, and the rectifier module 317c is electrically connected to the rectifier busbar 373c. Thus, each inductor 816a, 816b, 816c is electrically connected to one phase of the rectifier system 317.

FIGS. 10A and 10B are perspective interior views of another three-phase drive system 1005. The drive system 805 is similar to the drive system 305 (FIG. 3), but the drive system 805 includes a DC choke and is an example of a drive system that can be represented schematically as shown in FIG. 2B.

The DC choke includes an inductor 1015a, which is in the positive DC bus 311a and electrically connected to the output of the rectifier modules 317a, 317b, 317c and the capacitor system 318, and an inductor 1015b, which is in the negative DC bus 311b and is electrically connected to the output of the rectifier modules 317a, 317b, 317c and the capacitor system 318. The output of the rectifier modules 317a, 317b, 317c is electrically connected to the inductor 1015a by an electrical connection 1065a and to the inductor 1015b by an electrical connection 1065a. The inductor 1015a is electrically connected to the capacitor system 318 and the positive DC bus 311a by an electrical connection 1064a. The inductor 1015b is electrically connected to the capacitor system 318 and the negative DC bus 311b by an electrical connection 1064b.

FIGS. 11A and 11B show the electrical connections to the rectifier system 317 for the drive system 1005. Because the drive system 1005 includes the DC choke, the drive system 1005 can be configured without the AC inductor 816, and the electrical connections to the rectifier system 317 are modified to accommodate the lack of the AC inductor 816. The input busbar 371a is electrically connected to the rectifier busbar 373a by an electrical connection 1069a without a series inductor. Similarly, the input busbar 371b is electrically connected to the rectifier busbar 373b by an electrical connection 1069b without a series inductor, and the input busbar 371c is electrically connected to the rectifier busbar 373c by an electrical connection 1069c without a series inductor. The electrical connections 1069a, 1069b, 1069c are illustrated as busbars but may be any type of electrical connection.

These and other implementations are within the scope of the claims. For example, the three-phase drive system 305 shown in FIGS. 3, 4A, 4B, 5A, 6A-6C, 8, 10A, and 10B is illustrated as including the fan assembly 382 in the recessed region 381, which is formed in the side 326 at the top of the three-phase drive system 305. However, other implementations are possible. For example, the fan assembly 382 may be installed at the bottom of the three-phase drive system 305. Moreover, more than one fan assembly 382 may be used in the three-phase drive system 305. For example, there may be two fan assemblies 382, one in the recessed region 381 and the other at the bottom of the three-phase drive system 305.

Furthermore, although the fan assembly 382 is depicted as two blowers, any device or component capable of providing cooling may be used instead of or in addition the fan assembly 382. For example, axial fans or a non-blower type fan may be used with or instead of the two blowers.

What is claimed is:

1. A drive system comprising:
a structure;
an input comprising:
a first input section on a first side of the structure; and
a second input section on a second side of the structure;
an output comprising:
a first output section on the first side of the structure; and
a second output section on the second side of the structure; and
a power converter electrically connected to the output and the input.

2. The drive system of claim 1, wherein the structure is configured for rotation between a first position and a second position, and wherein, in the first position, the first side faces a first direction, and in the second position, the second side faces the first direction.

3. The drive system of claim 2, wherein the structure is configured for placement in a first type of mounting arrangement in the first position, and the structure is configured for placement in a second type of mounting arrangement in the second position.

4. The drive system of claim 3, wherein the first type of mounting arrangement comprises a wall mount arrangement, and the second type of mounting arrangement comprises a floor mount arrangement.

5. The drive system of claim 1, wherein the first side of the mounting structure is in a first plane and the second side of the mounting structure is in a second plane that is perpendicular to the first plane.

6. The drive system of claim 1, wherein the first side of the mounting structure and the second side of the mounting structure are in different planes.

7. The drive system of claim 1, wherein the first input section is electrically connected to the second input section; and the first output section is electrically connected to the second output section.

8. The drive system of claim 1, wherein the power converter comprises:
a rectifier electrically connected to the input;
an energy storage apparatus electrically connected to the rectifier; and
an inverter electrically connected to the energy storage apparatus and to the output.

9. The drive system of claim 8, further comprising a filter module between the rectifier and the energy storage apparatus.

10. The drive system of claim 9, wherein the filter module comprises at least one inductor.

11. The drive system of claim 10, wherein the filter module comprises a first inductor in a positive DC bus and a second inductor in a negative DC bus.

12. The drive system of claim 8, further comprising a filter module between the input and the rectifier.

13. The drive system of claim 12, wherein the filter module comprises a plurality of inductors.

14. The drive system of claim 1, further comprising a busbar subassembly, and wherein the busbar assembly electrically connects the input and the power converter, and the busbar assembly electrically connects the power converter and the output.

15. A busbar subassembly for connecting a first drive system and a second drive system in parallel, the busbar subassembly comprising:
a first electrically conductive busbar configured to electrically connect to a first drive system, the first electrically conductive busbar comprising: a first mounting portion that extends along a first direction, and a first connection portion that extends from the first mounting portion in a second direction; and
a second electrically conductive busbar configured to electrically connect to a second drive system, the second electrically conductive busbar comprising: a second mounting portion that extends along the first direction, and a second connection portion that extends from the second mounting portion in the second direction;
wherein the first connecting portion is configured for electrical connection to the second connection portion to thereby electrically connect the first drive system and the second drive system in parallel.

16. The busbar subassembly of claim 15, wherein the first direction and the second direction are perpendicular.

17. The busbar subassembly of claim 15, wherein the first electrically conductive busbar and the second electrically conductive busbar are L-shaped.

18. The busbar subassembly of claim 15, wherein the first mounting portion comprises at least one opening configured to receive a connector that protrudes from a busbar on the first drive system, and the second mounting portion comprises at least one opening configured to receive a connector that protrudes from a busbar on the second drive system.

19. The busbar subassembly of claim 15, wherein each of the first connection portion and the second connection portion comprises a planar surface, and the planar surfaces are placed in physical contact to electrically connect the first connection portion and the second connection portion.

20. A drive system comprising:
a support;
an input section configured to electrically connect to an external alternating current (AC) source;
a rectifier electrically connected to the input section;
an inverter,
a DC link electrically connected to the rectifier and the inverter, and
a filter system electrically connected to the input section and the rectifier, the filter system being internal to the support.

21. The drive system of claim 20, wherein the support is configured for rotation between a first position and a second position.
